(19) United States
(12) Patent Application Publication
(10) Pub. No.: US 2005/0099659 A1
(43) Pub. Date: May 12, 2005

(54) Image sensor module

(76) Inventors: Jichen Wu, Hsinchu Hsien (TW); Figo Hsieh, Hsinchu Hsien (TW)

Correspondence Address: Keith Kline;PRO-TECHTOR INTERNATIONAL SERVICES, 20775 Norada Court, Saratoga, CA, 95070-3018, US

(21) Appl. No.: 10/705,380

(22) Filed: Nov. 10, 2003

(51) Int. Cl. H04N 1/024; H01L 23/02

(52) U.S. Cl. 358/482; 257/678

(57) ABSTRACT

An image sensor module includes a substrate, a photosensitive chip, a lens holder and a lens barrel. The substrate has a upper surface and a lower surface. The photosensitive chip is arranged at the upper surface of the substrate, and electrically connected the substrate by a plurality of wires. The lens holder is formed with a penetrated hole at a central thereof, an internal thread being formed on the inner wall of the penetrate hole, the lens holder being mounted on the upper surface of the first substrate to encapsulate the photosensitive chip. The lens barrel is arranged within the penetrate hole of the lens holder and is formed with an external thread, which is screwed to the internal thread of the lens holder.

### BACKGROUND OF THE INVENTION

1. Field of the Invention

The invention relates to an image sensor module, and in particular to an image sensor having reduced volume and positioned easily.

2. Description of the Related Art

A general sensor is used to sense signals, which may be optical or audio signals. The sensor of the invention is used to receive image signals or optical signals. After receiving the image signals, the sensor converts the image signals into electrical signals, which are then transmitted to a printed circuit board via a substrate.

Referring to FIG. 1, a conventional image sensor module includes a lens holder 10, a lens barrel 20, and an image sensor 30. The lens holder 10 has an upper end face 12, a lower end face 14 and an opening 16 penetrating through the lens holder 10 from the upper end face 12 to the lower end face 14. An internal thread 18 is formed on an inner wall of the opening 16 of the lens holder 10. The lens barrel 20 formed with an external thread 22 is inserted from the upper end face 12 of the lens holder 10, received within the opening 16, and screwed to the internal thread 18 of the lens holder 10. The lens barrel 20 is formed with a transparent region 24 under which an aspheric lens 26 and an infrared filter 28 are arranged in sequence. The image sensor 30 has a first surface 32 and a second surface 34 opposite to the first surface 32 on which a transparent layer 36 is surface 34 opposite to the first surface 32 on which a transparent layer 36 is arranged. The image sensor 30 is bonded to the lower end face 14 of the lens holder 10 through the transparent layer 36. The screwed length between the lens barrel 20 and the lens holder 10 may be adjusted to control the distance from the aspheric lens 26 of the lens barrel 20 to the transparent layer 36 of the image sensor 30.

The above-mentioned image sensor module has the following drawbacks.

1. Because the image sensor 30 is bonded to the lower end face 14 of the lens holder 10 through the transparent layer 36, the image sensor 30 cannot be replaced when the image sensor 30 of the module is damaged. In this case, the overall module has to be treated as waste material, and other good elements in the module may not be recycled.

2. Because the transparent layer 36 is bonded to the lower end face 14 of the lens holder 10 by the adhesive, which may contaminate the surface of the transparent layer 36, poor optical signals may be obtained.

3. When the module is assembled, the transparent layer 36 has to be precisely positioned with the aspheric lens 26 and then bonded to the lens barrel 20. Once the positional precision deviates from the standard level, the overall module cannot be reassembled and has to be treated as waste material.

4. The lens holder 10 has to be additionally provided to combine the lens barrel 20 with the image sensor 30.

### SUMMARY OF THE INVENTION

An object of the present invention is to provide an image sensor module having manufacturing easily.

Another object of the present invention is to provide an image sensor module having a reduced and miniaturized package volume.

To achieve the above-mentioned objects, the invention provides a first substrate, which have a upper surface and a lower surface, the upper surface is formed with a plurality of first connected ends, the lower surface is formed with a plurality of second connected ends. A photosensitive chip is arranged at the upper surface of the substrate, and is electrically connected the first connected ends by a plurality of wires. A lens holder is formed with penetrate hole at a central thereof, an internal thread is formed on the inner wall of the penetrate hole, the lens holder is mounted on the upper surface of the first substrate to encapsulate the photosensitive chip. A lens barrel is arranged within the penetrate hole of the lens holder and is formed with an external thread, which is screwed to the internal thread of the lens holder, the lens barrel is formed with a chamber and an opening communicating the chamber.

### BRIEF DESCRIPTION OF THE DRAWINGS

FIG. 1 is a cross-sectional view showing a conventional image sensor module.

FIG. 2 is a cross-sectional view showing an image sensor module of the present invention.

FIG. 3 is an exploded cross-sectional view showing an image sensor module of the present invention.

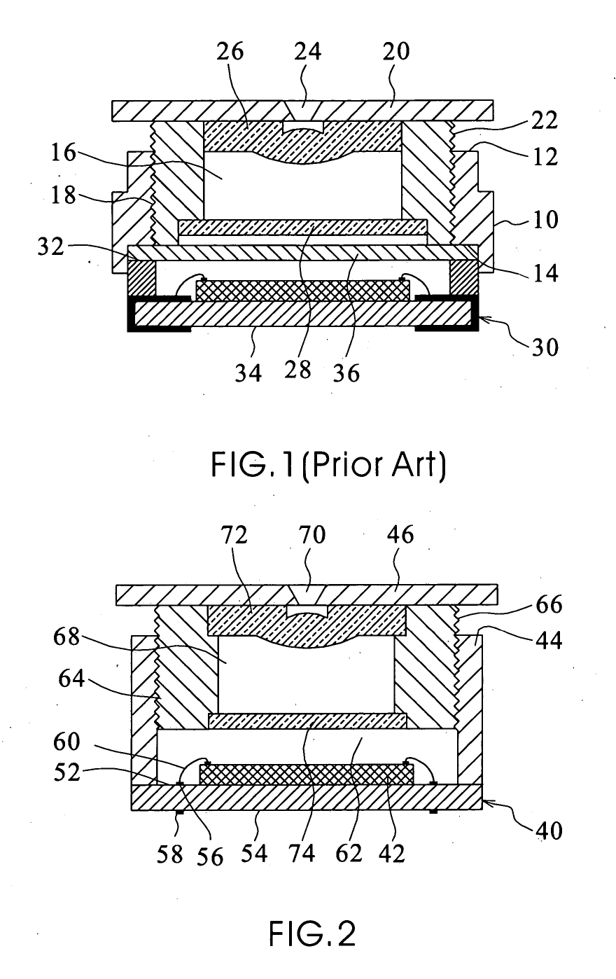

### DETAILED DESCRIPTION OF THE INVENTION

Referring to FIG. 2, an image sensor module of the present invention includes a substrate 40, a photosensitive chip 42, a lens holder 44, and a lens barrel 46.

The substrate 40 has an upper surface 52 and a lower surface 54, the upper surface 52 is formed with a plurality of first connected ends 56, the lower surface 54 is formed with a plurality of second connected ends 58.

The photosensitive chip 42 is arranged at the upper surface 52 of the substrate 40, and is electrically connected the first connected ends 56 of the substrate 40 by a plurality of wires 60.

The lens holder 46 is formed with penetrated hole 62 at a central thereof, an internal thread 64 is formed on the inner wall of the penetrated hole 62, the lens holder 46 is mounted on the upper surface 52 of the first substrate 40 to encapsulate the photosensitive chip 42.

The lens barrel 46 is arranged within the penetrate hole 62 of the lens holder 46 and is formed with an external thread 66, which is screwed to the internal thread 64 of the lens holder 64, the lens barrel 46 is formed with a chamber 68 and an opening 70 communicating the chamber 68. An aspheric 72 and transparent layer 74 are placed within the chamber 68.

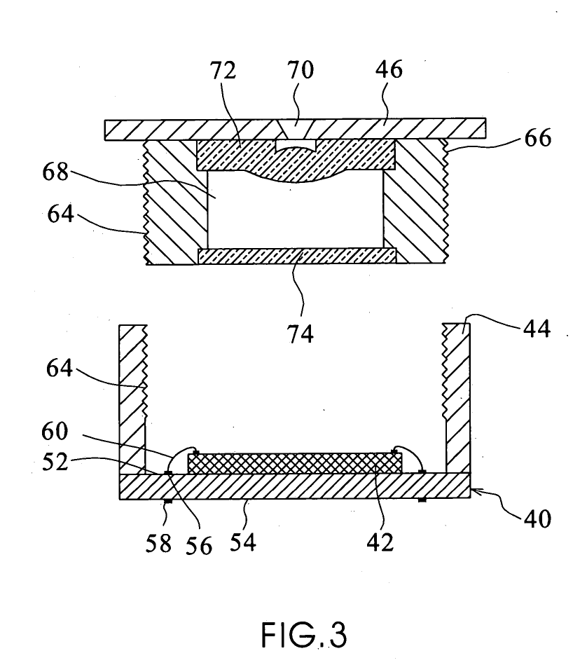

Please referring to FIG. 3, is an exposed cross-sectional view showing an image sensor module of the present invention. A method of manufacturing the image sensor module includes the steps.

Providing a substrate 40 has an upper surface 52 and a lower surface 54, the upper surface 52 is formed with a plurality of first connected ends 56, the lower surface 54 is formed with a plurality of second connected ends 58.

Providing a photosensitive chip 42 is arranged at the upper surface 52 of the substrate 40, and is electrically connected the first connected ends 56 of the substrate 40 by a plurality of wires 60.

Providing a lens holder 46 is formed with penetrated hole 62 at a central thereof, an internal thread 64 is formed on the inner wall of the penetrated hole 62, the lens holder 46 is mounted on the upper surface 52 of the first substrate 40 to encapsulate the photosensitive chip 42.

Providing a ens barrel 46 is arranged within the penetrate hole 62 of the lens holder 46 and is formed with an external thread 66, which is screwed to the internal thread 64 of the lens holder 64, the lens barrel 46 is formed with a chamber 68 and an opening 70 communicating the chamber 68. An aspheric 72 and transparent layer 74 are placed within the chamber 68.

The image sensor module of the invention has the following advantages.
1. Since the lens holder is directly arranged at the substrate, so present invention bay be reduced and miniaturized the package volume.
2. Since the wires 58 are bonded to the upper surface 48 of the substrate 40, the gap between the substrate 40 and the photosensitive chip 44 may be reduced, and the package volume of the image sensor may be effectively miniaturized.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

1. A image sensor module, comprising:
a substrate having a upper surface and a lower surface, the upper surface formed with a plurality of first connected ends, the lower surface formed with a plurality of second connected ends;
a photosensitive chip arranged at the upper surface of the substrate, and electrically connected the first connected ends by a plurality of wires;
a lens holder formed with a penetrated hole at a central thereof, an internal thread being formed on the inner wall of the penetrated hole, the lens holder being mounted on the upper surface of the first substrate to encapsulate the photosensitive chip; and
a lens barrel arranged within the penetrate hole of the lens holder and is formed with an external thread, which is screwed to the internal thread of the lens holder, the lens barrel being formed with a chamber and an opening communicating the chamber, a aspheric and a transparent layer are arranged within the chamber.

2. The image sensor module according to claim 1, wherein the transparent layer is an infrared filter.

3. a method for manufacturing an image sensor module, comprising the steps:
providing a substrate having a upper surface and a lower surface, the upper surface formed with a plurality of first connected ends, the lower surface formed with a plurality of second connected ends;
providing a photosensitive chip arranged at the upper surface of the substrate, and electrically connected the first connected ends by a plurality of wires;
providing a lens holder formed with a penetrate hole at a central thereof, an internal thread being formed on the inner wall of the penetrate hole, the lens holder being mounted on the upper surface of the first substrate to encapsulate the photosensitive chip; and
providing a lens barrel arranged within the penetrate hole of the lens holder and is formed with an external thread, which is screwed to the internal thread of the lens holder, the lens barrel being formed with a chamber and an opening communicating the chamber, a aspheric and a transparent layer are arranged within the chamber.
